(19) United States
(12) Patent Application Publication
(10) Pub. No.: US 2017/0324219 A1
(43) Pub. Date: Nov. 9, 2017

(54) SEMICONDUCTOR LASER INCORPORATING AN ELECTRON BARRIER WITH LOW ALUMINUM CONTENT

(71) Applicant: MACOM Technology Solutions Holdings, Inc., Lowell, MA (US)

(72) Inventor: Mark CROWLEY, Ithaca, NY (US)

(73) Assignee: MACOM Technology Solutions Holdings, Inc., Lowell, MA (US)

(21) Appl. No.: 15/586,072

(22) Filed: May 3, 2017

Related U.S. Application Data
(60) Provisional application No. 62/332,085, filed on May 5, 2016.

(51) Int. Cl. H01S 5/22; H01S 5/343

(52) U.S. Cl. CPC H01S 5/2205; H01S 5/34326; H01S 5/3434

(57) ABSTRACT

A semiconductor laser may include a substrate, an active region, and an electron stopper layer. The electron stopper layer may include an aluminum gallium indium arsenide phosphide alloy. The aluminum gallium indium arsenide phosphide alloy may have an AlₓGa_{y}In_{(1-x-y)}As_{z}P_{(1-z)} composition.

### CROSS-REFERENCE TO RELATED APPLICATIONS

This patent application claims priority to U.S. Provisional Patent Application No. 62/332,085, filed on May 5, 2016, the contents of which are incorporated by reference herein in their entirety.

### FIELD OF THE DISCLOSURE

The present disclosure relates generally to semiconductor lasers and, more particularly, to semiconductor lasers incorporating an active region which is sandwiched between charge carrier stopper layers having low aluminum content.

### BACKGROUND OF THE DISCLOSURE

With today's insatiable demand for Internet data, the infrastructure of data centers and mobile communications may require state of the art high speed lasers with ultra-fast modulation speeds. Semiconductor lasers typically may employ precise engineering techniques that allow a device to efficiently generate coherent light as well as making it possible to modulate these light signals at high speeds. A typical semiconductor laser may comprise a series of many semiconductor layers sandwiched together, all with unique functions. Electron and hole stopper layers may surround an active region of the laser with the function of reducing electron and hole leakage (i.e., current leakage) out of the active region. The aforementioned current leakage can significantly limit laser performance as it may limit the amount of electron-hole pairs available to the active region for stimulated emission.

Conventional ridge waveguide lasers have enjoyed widespread use since they may be relatively simple to manufacture. However, in such structures, electrical current may not be delivered efficiently to the active region resulting in a significant amount of current flowing into the residual semiconductor material outside the ridge and above the active region. Eliminating this parasitic current path may be essential in order to realize fast switching high speed lasers. Laser structures such as the buried heterostructure, buried ridge, and buried crescent may be typical arrangements which may fulfill the task of blocking lateral current flow, thereby minimizing a threshold current required for lasing. In a ridge waveguide configuration, electron and hole stopper layers may be made of an alloy comprising at least 48% aluminum. However, such high levels of aluminum may not be suitable to incorporate within high performance laser structures such as buried heterostructures mentioned above. Such structures may seek to minimize lateral current leakage by etching through the active region. However, in fabricating these structures, any aluminum containing layer may be prone to material degradation due to oxidation. Accordingly, there may be a need for a device including an electron stopper layer with low aluminum content.

### SUMMARY OF THE DISCLOSURE

In some embodiments, a semiconductor laser may include a substrate, an active region, and an electron stopper layer. The electron stopper layer may include an aluminum gallium indium arsenide phosphide alloy. The aluminum gallium indium arsenide phosphide alloy may have an AlₓGa_{y}In_{(1-x-y)}As_{z}P_{(1-z)} composition.

In some embodiments, the content amount x of the AlₓGa_{y}In_{(1-x-y)}As_{z}P_{(1-z)} composition may range from 0.20 to 0.55.

In some embodiments, the content amount y of the AlₓGa_{y}In_{(1-x-y)}As_{z}P_{(1-z)} composition may be 0, and the AlₓGa_{y}In_{(1-x-y)}As_{z}P_{(1-z)} composition may have an Al_{0.3}In_{0.7}As_{0.5}P_{0.5} composition.

In some embodiments, the content amount y of the AlₓGa_{y}In_{(1-x-y)}As_{z}P_{(1-z)} composition may be 0, and the AlₓGa_{y}In_{(1-x-y)}As_{z}P_{(1-z)} composition may have an Al_{0.35}In_{0.65}As_{0.5}P_{0.5} composition.

In some embodiments, the content amount y of the AlₓGa_{y}In_{(1-x-y)}As_{z}P_{(1-z)} composition may be 0, and the AlₓGa_{y}In_{(1-x-y)}As_{z}P_{(1-z)} composition may have an Al_{0.4}In_{0.6}As_{0.5}P_{0.5} composition.

In some embodiments, a lattice constant of the electron stopper layer may be matched to a lattice constant of the substrate.

In some embodiments, a lattice constant of the electron stopper layer may have a lattice mismatch relative to a lattice constant of the substrate.

In some embodiments, the lattice constant of the electron stopper layer may have a lattice mismatch within ±1% relative to the lattice constant of the substrate.

In some embodiments, the substrate may include indium phosphide (InP). In some embodiments, the content amount y of the AlₓGa_{y}In_{(1-x-y)}As_{z}P_{(1-z)} composition may be 0, and the AlₓGa_{y}In_{(1-x-y)}As_{z}P_{(1-z)} composition may be an AlₓIn₍₁₋ₓ₎As_{z}P_{(1-z)} composition.

In some embodiments, the semiconductor laser may further include an n-type cladding layer, a multi quantum well (MQW) active layer that may be arranged adjacent to the n-type cladding layer, and a p-type cladding layer that may be arranged adjacent to the electron stopper layer. The electron stopper layer may be arranged between the MQW active layer and the p-type cladding layer, and the p-type cladding layer may include a ridge waveguide structure. In some embodiments, the semiconductor laser may further include a hole stopper layer that may be arranged adjacent to the n-type cladding layer. The hole stopper layer may include an aluminum gallium indium arsenide phosphide alloy having an AlₓGa_{y}In_{(1-x-y)}As_{z}P_{(1-z)} composition. The content amount x may range from 0.20 to 0.55.

In some embodiments, the content amount y of the AlₓGa_{y}In_{(1-x-y)}As_{z}P_{(1-z)} composition may be 0, and the AlₓGa_{y}In_{(1-x-y)}As_{z}P_{(1-z)} composition may be an AlₓIn₍₁₋ₓ₎As_{z}P_{(1-z)} composition.

In some embodiments, a quantum well of the MQW active layer may be compressively strained and a barrier of the MQW active layer may be tensile strained. A lattice mismatch of the quantum well relative to a lattice constant of the substrate may be within 2%. A lattice mismatch of the barrier relative to the lattice constant of the substrate may be within 2%.

In some embodiments, a quantum well of the MQW active layer may be tensile strained and a barrier of the MQW active layer may be compressively strained. A lattice mismatch of the quantum well relative to a lattice constant of the substrate may be within 2%. A lattice mismatch of the barrier relative to the lattice constant of the substrate may be within 2%.

In some embodiments, a semiconductor laser may include a substrate, an active region, a lateral current blocking material, and an electron stopper layer. The electron stopper layer may be configured to reduce oxidation and form an interface with the current blocking material. The electron stopper layer may include an aluminum gallium indium arsenide phosphide alloy having an AlₓGa_{y}In_{(1-x-y)}As_{z}P_{(1-z)} composition.

In some embodiments, the content amount x of the AlₓGa_{y}In_{(1-x-y)}As_{z}P_{(1-z)} composition may range from 0.20 to 0.55.

In some embodiments, the content amount y of the AlₓGa_{y}In_{(1-x-y)}As_{z}P_{(1-z)} composition may be 0, and the AlₓGa_{y}In_{(1-x-y)}As_{z}P_{(1-z)} composition may have an Al_{0.3}In_{0.7}As_{0.5}P_{0.5} composition.

In some embodiments, the content amount y of the AlₓGa_{y}In_{(1-x-y)}As_{z}P_{(1-z)} composition may be 0, and the AlₓGa_{y}In_{(1-x-y)}As_{z}P_{(1-z)} composition has an Al_{0.35}In_{0.65}As_{0.5}P_{0.5} composition.

In some embodiments, the content amount y of the AlₓGa_{y}In_{(1-x-y)}As_{z}P_{(1-z)} composition may be 0, and the AlₓGa_{y}In_{(1-x-y)}As_{z}P_{(1-z)} composition may have an Al_{0.4}In_{0.6}As_{0.5}P_{0.5} composition.

In some embodiments, a quantum well of an MQW active layer may be compressively strained and a barrier of the MQW active layer may be tensile strained. A lattice mismatch of the quantum well relative to a lattice constant of the substrate may be within 2%. A lattice mismatch of the barrier relative to the lattice constant of the substrate may be within 2%.

In some embodiments, a quantum well of an MQW active layer may be tensile strained and a barrier of the MQW active layer may be compressively strained. A lattice mismatch of the quantum well relative to a lattice constant of the substrate may be within 2%. A lattice mismatch of the barrier relative to the lattice constant of the substrate may be within 2%.

In some embodiments, a method of fabricating a semiconductor laser may include arranging an n-type cladding layer on a substrate, arranging a hole stopper layer on the n-type cladding layer, arranging a multi quantum well (MQW) active layer on the hole stopper layer, arranging an electron stopper layer on a multi quantum well (MQW) active layer, and arranging a current blocking material adjacent to the n-type cladding layer, hole stopper layer, MQW active layer, and electron stopper layer. The electron stopper layer may be configured to reduce oxidation and form an interface with the current blocking material. The electron stopper layer may include an aluminum gallium indium arsenide phosphide alloy having an AlₓGa_{y}In_{(1-x-y)}As_{z}P_{(1-z)} composition.

In some embodiments, the content amount x of the AlₓGa_{y}In_{(1-x-y)}As_{z}P_{(1-z)} composition may range from 0.20 to 0.55.

In some embodiments, a quantum well of the MQW active layer may be compressively strained and a barrier of the MQW active layer may be tensile strained. A lattice mismatch of the quantum well relative to a lattice constant of a substrate may be within 2%. A lattice mismatch of the barrier relative to the lattice constant of the substrate may be within 2%.

In some embodiments, a quantum well of the MQW active layer may be tensile strained and a barrier of the MQW active layer may be compressively strained. A lattice mismatch of the quantum well relative to a lattice constant of a substrate may be within 2%. A lattice mismatch of the barrier relative to the lattice constant of the substrate may be within 2%.

The present disclosure will now be described in more detail with reference to particular embodiments thereof as shown in the accompanying drawings. While the present disclosure is described below with reference to particular embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be illustrative only.

FIG. 1 shows a three-dimensional offset view of a semiconductor ridge waveguide laser.

FIG. 2 shows a cross sectional view of a semiconductor ridge waveguide laser.

FIG. 3 shows a three-dimensional offset view of a buried ridge laser in accordance with an embodiment of the present disclosure.

FIG. 4 shows a cross sectional view of a buried ridge laser.

FIG. 5A shows a semiconductor laser stack and FIG. 5B shows a zoomed view of a portion of the semiconductor laser stack of FIG. 5A.

FIG. 6 shows a chart of conduction band offsets of common III-V binary semiconductor materials against their respective lattice constants in accordance with an embodiment of the present disclosure.

FIG. 7 shows a chart of conduction band offsets of commonly used III-V binary substrate material and conventional lattice-matched ternary electron stopper alloys in accordance with an embodiment of the present disclosure.

FIG. 8 shows a chart of conduction band offsets against lattice constants as per FIG. 7 but now including the novel AlInAsP electron stopper material alloy in accordance with an embodiment of the present disclosure.

FIG. 9 shows a chart of optical power output for a variety of electron stopper materials in a semiconductor laser in accordance with an embodiment of the present disclosure.

FIG. 10 shows Table 1, which shows a list of AlₓGa_{y}In_{(1-x-y)}As_{z}P_{(1-z)} alloy content amounts.

FIG. 11 shows Table 2, which shows another list of AlₓGa_{y}In_{(1-x-y)}As_{z}P_{(1-z)} alloy content amounts.

FIG. 12 shows a chart of experimental results of optical power output for electron stopper materials in semiconductor lasers in accordance with an embodiment of the present disclosure.

### DETAILED DESCRIPTION OF EMBODIMENTS

In the following description, numerous specific details are set forth regarding the systems and methods of the disclosed subject matter and the environment in which such systems and methods may operate in order to provide a thorough understanding of the disclosed subject matter. It will be apparent to one skilled in the art, however, that the disclosed subject matter may be practiced without such specific details, and that certain features, which are well known in the art, are not described in detail in order to avoid complication of the disclosed subject matter. In addition, it will be understood that the examples provided below are exemplary, and that it is contemplated that there are other systems and methods that are within the scope of the disclosed subject matter.

Embodiments of the disclosure are directed to improved electron barrier layer materials in a semiconductor laser device. Semiconductor lasers are compact lasers formed through the use of electrically stimulated p-n junctions. Many types of semiconductor laser structures have been produced, each of which has its own advantageous characteristics. One such laser that has seen particularly strong demand is known as a Ridge Waveguide Laser (RWG laser).

In an RWG laser, a cladding material that covers the top of the laser device is etched during fabrication to form a ridge. However, there remains a residual thickness of material outside the ridge and above the active region, the consequence of which may be a significant lateral current loss. This current spreading may cause undesirable inefficiencies in the device, significantly impacting laser threshold current and modulation bandwidth.

To alleviate the above issues with RWG lasers, many technologies have been developed. In each case, the goal may be to limit the lateral extent of the device in order to eliminate lateral current loss. An exemplary structure is a buried ridge laser. In a buried ridge laser, the ridge area of a RWG laser is further etched through the cladding and the active area of the laser down to the lower cladding material of the device. By etching through the cladding and active area of the laser, no current spreading may occur in principle. However, exposing the aluminum containing layers of the laser to the air may cause the formation of oxidized interfaces. Unfortunately, this then may result in a degradation of the current blocking material which is regrown adjacent to these oxidized Al interfaces. To ensure good quality interfaces and the ability to remove any aluminum oxide prior to the regrowth on the etched ridge, the aluminum composition in these materials may be limited to no higher than approximately 30%.

In conventional RWG lasers, the electron stopper layer may be made of a material containing crystals with high amounts (48%) of aluminum. To solve the above problems with current buried ridge lasers, embodiments of the disclosure may provide devices and methods for generating a high performance electron stopper with a low aluminum content. In particular, embodiments of the disclosure may provide a novel electron stopper material of aluminum indium arsenide phosphide, containing 30% aluminum. This material may provide comparable performance to current used alloys while containing a sufficiently low aluminum content to reduce oxidation.

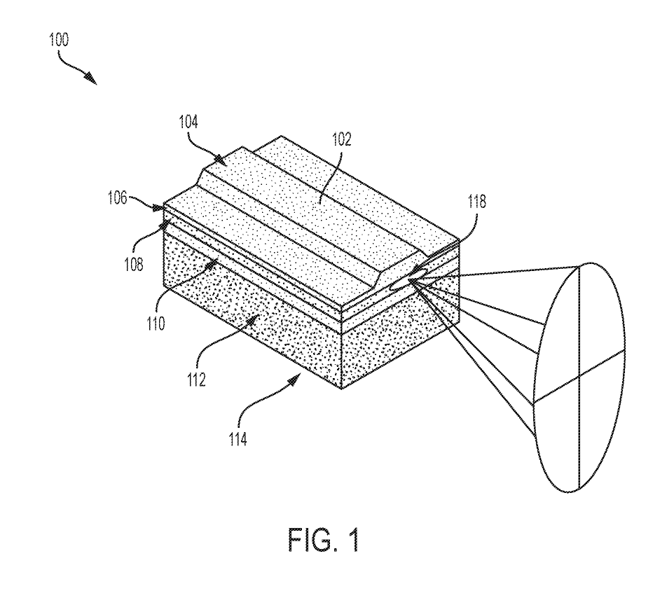

Referring to FIG. 1, a three-dimensional offset view of a semiconductor laser is shown. In FIG. 1, laser 100 is an RWG semiconductor laser device that is adapted to produce a laser emission beam of a specific optical frequency. Laser 100 comprises p-type cladding layer 106 having ridge 104, active layer 108, n-type cladding layer 110, substrate 112, and output facet 118. An anode metallization layer 102 may be deposited on a top surface of ridge 104, and a cathode metallization layer 114 may be deposited on a bottom surface of substrate 112. These metallization layers form an electrical contact with the underlying semiconductor material.

Anode metallization layer 102 can be a metallization formed of any conductive material sufficient to create a low resistance electronic contact with ridge 104. The resistance is low relative to the stack of layers, and may provide an ohmic contact that does not add significant resistance to the resistance of the stack of layers. For example, anode metallization layer 102 can be made of three metallic sublayers, namely titanium, platinum, and gold, deposited on ridge 104.

Ridge 104 can be a design formed within p-type cladding layer 106 that forms a rectangular or trapezoidal shape over the top of the full width of p-type cladding layer 106. The shape of ridge 104 is not limited to a rectangular prism, and may be other shapes such as a dovetailed ridge. Ridge 104 is generated by etching away the material that forms p-type cladding layer 106, which initially extends to cover the entire width and height of semiconductor laser 100. Ridge 104 can be composed of a variety of p-type semiconductor materials, but typically will be the same material as p-type cladding layer 106. In one example, ridge 104 can be made of p-type doped Indium Phosphide (InP), but an Indium Gallium Arsenide (InGaAs) layer may be disposed at the top of ridge 104 upon which anode metallization layer 102 is deposited.

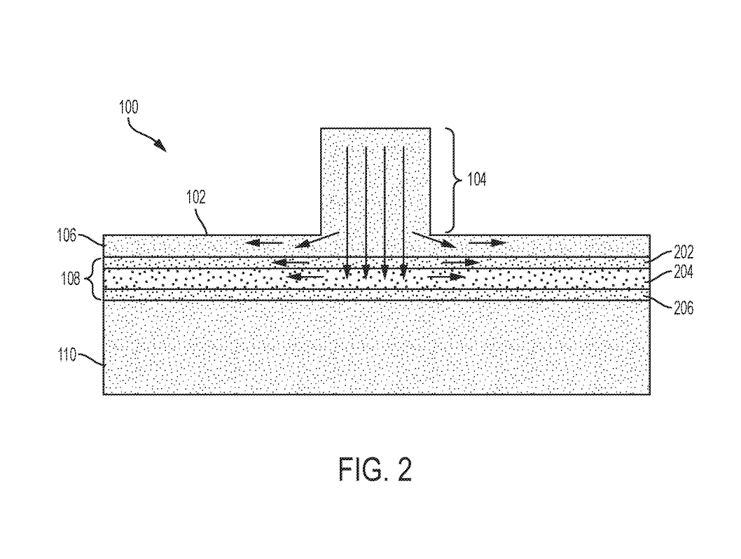

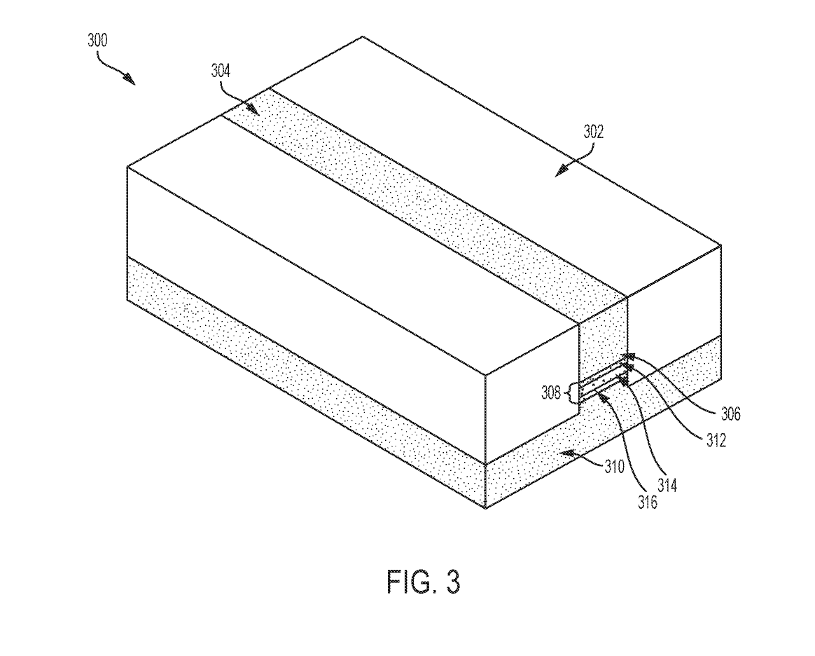

P-type cladding layer 106 can be a material that completely covers the top of active layer 108. P-type cladding layer 106 is a layer directly over the top of active layer 108 through which current can be conducted. Typically, ridge 104 will fabricated by etching away part of the material forming p-type cladding layer 106 over the top of active layer 108. The design of ridge 104 permits current to flow from the top of the laser through the active layer 108 within the spatial dimensions of the ridge structure, as shown in FIG. 1. However, as will be shown in FIG. 2, the current cannot be limited to flow only under the location of the ridge 104; some current will inevitably spread to portions of p-type cladding layer 106 that are not located under the ridge 104. Although p-type cladding layer 106 can be any number of different materials, in one exemplary implementation, p-type cladding layer 106 can be p-type doped Indium Phosphide (InP).

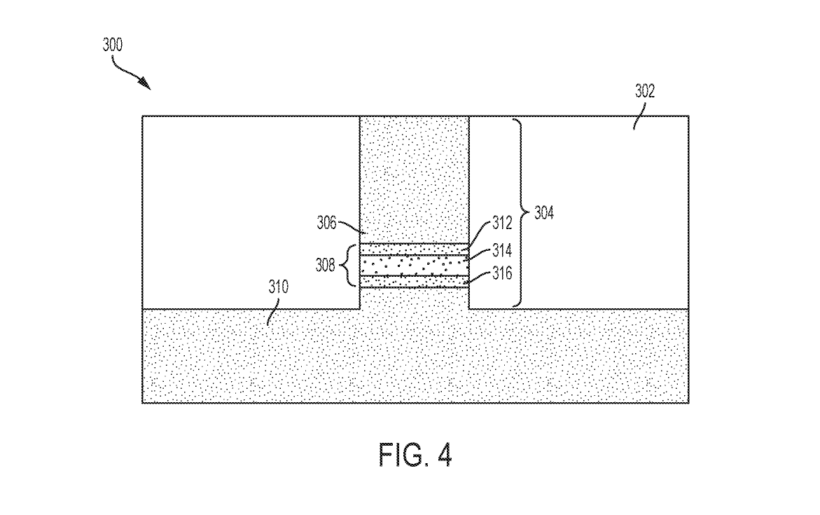

As will be discussed in more detail in FIGS. 2 and 4, active layer 108 is a stack of materials that generates the coherent laser light via stimulated emission. Among other materials, active layer 108 contains an electron stopper layer, a stack of quantum wells with barriers between the quantum wells (multi-quantum well (MQW) stack), and a hole stopper layer. As will be described in more detail in FIG. 4, the sublayers of active layer 108 are alloys with a crystal structure that contain some amount of aluminum.

N-type cladding layer 110 can be a material that completely covers the bottom of active layer 108. N-type cladding layer 110 is a layer directly under the bottom of active layer 108 through which current can be conducted. As with p-type cladding layer 106, because n-type cladding layer 110 is wider than the width of ridge 104, current can flow through n-type cladding layer 110 in a wider area than current flows through ridge 104. Although n-type cladding layer 110 can be any number of different materials, in one exemplary implementation n-type cladding layer 110 can be n-type doped Indium Phosphide (InP).

Substrate 112 can be a semiconductor substrate material that forms the base of semiconductor laser 100. Although substrate 112 can be any number of different materials, in one exemplary implementation substrate can be n-type indium phosphide (InP).

Cathode metallization layer 114 can be a metallization formed of any conductive material sufficient to create a low resistance electronic contact with substrate 112.

Referring to FIG. 2, a cross-sectional view of a semiconductor laser is shown. In FIG. 2, the laser 100 of FIG. 1 is shown from a different perspective. As in FIG. 1, laser 100 is a semiconductor laser device that is adapted to produce laser emission beam of a specific optical frequency. Laser 100 contains p-type cladding 106 layer having ridge 104, active layer 108, and n-type cladding layer 110. Active layer 108 comprises electron stopper layer 202, MQW active layer 204, and hole stopper layer 206.

As discussed below, in a semiconductor laser, electrons and holes flow in opposite directions across a stack of materials with different bandgaps to recombine and generate photons in the laser active region. To confine electrons and holes in appropriate locations within active layer 108, an electron stopper layer 202 is disposed between p-type cladding layer 106 and MQW active region 204. In addition, a hole stopper layer 206 is disposed between n-type cladding layer 110 and MQW active region 204.

Electron stopper layer 202 is a material that is specially adapted to prevent electrons from flowing away from MQW active layer 204 towards p-type cladding layer 106. In a typical ridge waveguide laser, for example, the semiconductor laser 100 of FIGS. 1 and 2, electron stopper layer 202 comprises p-type doped aluminum indium arsenide (Al_{0.48}In_{0.52}As). Like all layers of active layer 108, electron stopper layer 202 is an alloy of aluminum.

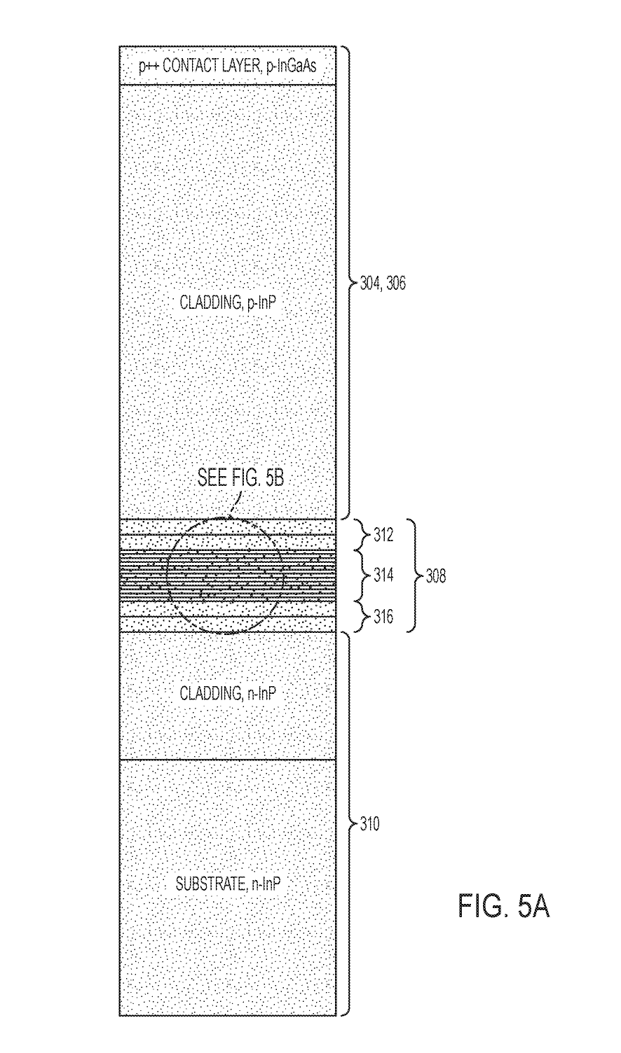

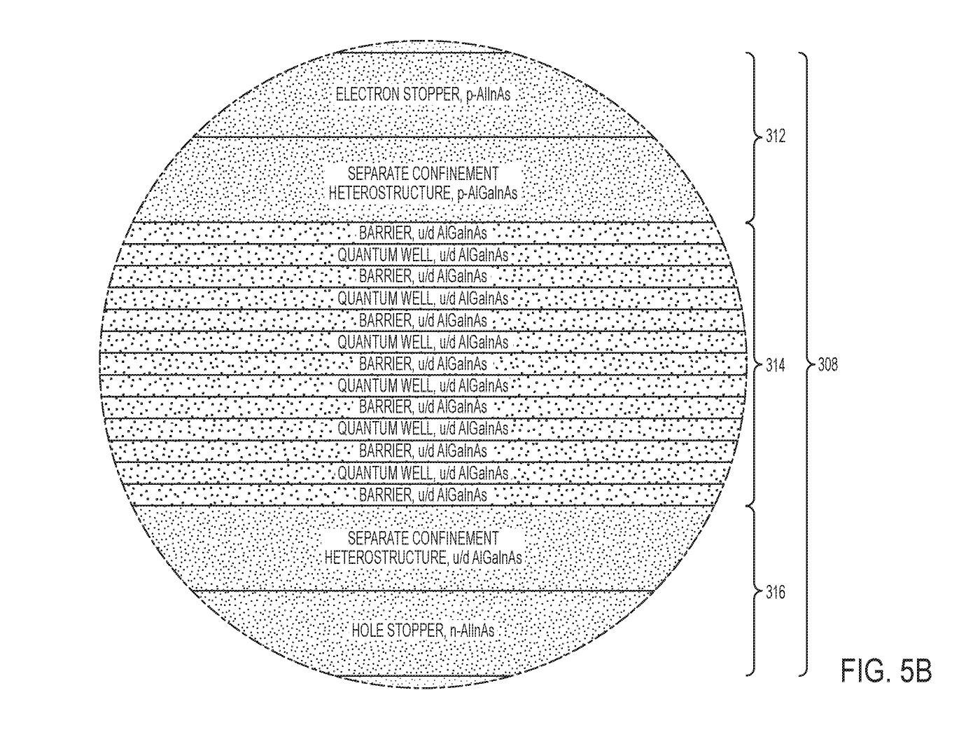

MQW active layer 204 is a stack of materials that form a plurality of quantum wells where electrons and holes can recombine to generate photons which are emitted as a coherent beam of light through facet 118 of laser 100. The precise content of MQW active layer 204 will be described more fully with respect to FIG. 5B. In a typical ridge waveguide laser, for example, the semiconductor laser 100 of FIGS. 1 and 2, MQW active layer 204 comprises a series of layers, each of which comprises aluminum gallium indium arsenide (AlGaInAs).

Hole stopper layer 206 is a material that is specially adapted to prevent holes from flowing away from MQW active layer 204. In a typical ridge waveguide laser, for example, the semiconductor laser 100 of FIGS. 1 and 2, hole stopper layer 206 comprises n-type doped aluminum indium arsenide (AlInAs).

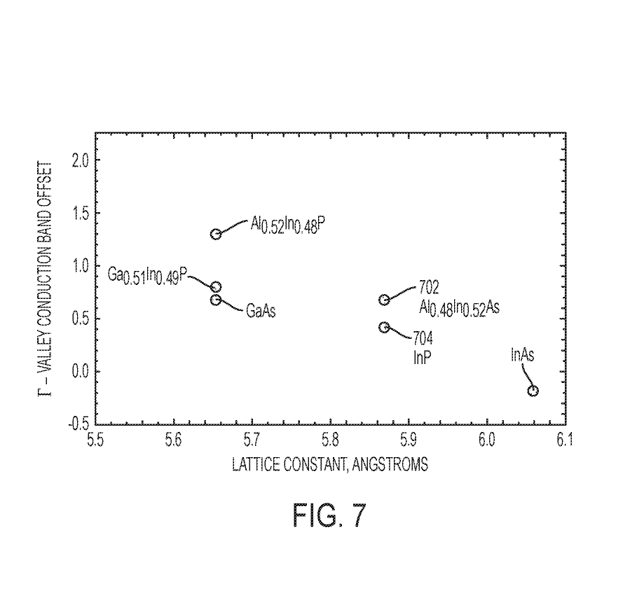

To avoid excessive strain with respect to the surrounding materials, the lattice constants of both the electron stopper and hole stopper layers are usually matched to the lattice constant of the material that forms semiconductor substrate 112. In the laser of FIGS. 1 and 2, the lattice constant of substrate 112 is precisely matched to the lattice constant of electron stopper layer 202 and hole stopper layer 206. As will be discussed with respect to FIG. 7, the lattice constants of both these materials is matched to InP which is approximately 5.875 angstroms.

Referring to FIG. 3, a three-dimensional offset view of a buried ridge type semiconductor laser 300 is shown. In FIG. 3, laser 300 is a semiconductor laser device that is adapted to produce a coherent laser beam of a specific optical frequency. Laser 300 contains p-type cladding 306 having ridge 304, active layer 308, and n-type cladding 310. Active layer 308 comprises electron stopper layer 312, Multi Quantum Well (MQW) active layer 314, and hole stopper layer 316. Further, laser 300 contains current blocking material 302, that is typically Fe-doped InP.

The buried ridge laser 300 of FIG. 3 operates in a similar manner to the ridge waveguide laser of FIGS. 1 and 2, and elements of buried right laser 300 (e.g., elements 304, 306, 308, 310, 312, 314, 316, etc.) may be similar to those discussed above in regard to the corresponding elements of laser 100 (e.g., elements 104, 106, 108, 110, 202, 204, 206, etc.). However, lateral current flow away from a center line of the active layer 204 in the semiconductor laser 100 of FIGS. 1 and 2 is inhibited. In the buried ridge laser of FIG. 3, etching through p-type cladding 106, active layer 108, and partially through n-type cladding 110 occurs. By etching through these layers, the buried ridge laser of FIG. 3 prevents current spreading since the cladding and active regions are limited dimensionally to only be as wide as required to optimize the overlap of the optical mode with the injected current. In this way, efficiency of the laser can be greatly improved.

Since many of the above newly etched layers contain aluminum, exposing them degrades the quality of the newly formed surfaces via oxidation which subsequently degrades the interface then formed with the regrown current blocking material 302. To reduce oxidation of these layers and allow removal of aluminum oxide layers prior to regrowth that is needed in a buried ridge laser design, it may be necessary to limit aluminum content in each of electron stopper layer 312, MQW active layer 314, and hole stopper layer 316. In the electron stopper layer 312, like in layer 202 for laser 100, the material provided in laser 300 may be aluminum indium arsenide (AlInAs). However, the AlInAs alloy used as the electron stopper layer 312 in laser 300 (like layer 202 in laser 100) may be composed of 48% aluminum (Al_{0.48}In_{0.52}As), which may be undesirable in view of difficulty of removing the aluminum oxide that is formed prior to regrowth. Therefore, a new material that functions as an electron barrier layer for electron stopper layer 312 in buried ridge laser 300 may be desired. Furthermore, a new material that functions as an electron barrier layer for electron stopper layer 202 in laser 100 may also be desired to improve performance of this laser.

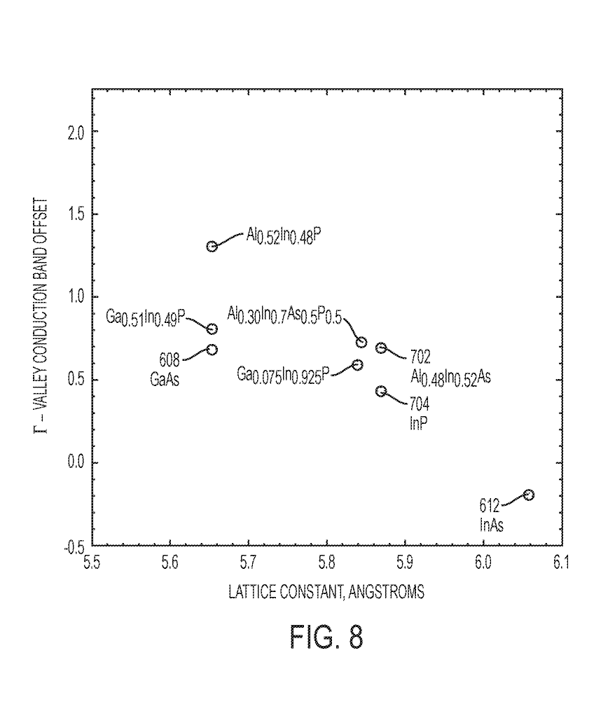

Embodiments of the disclosure provide a novel material for use as an electron barrier layer. As discussed with respect to FIG. 2, a typical electron stopper layer 202 for a ridge waveguide laser 100 may be p-type doped aluminum indium arsenide (Al_{0.48}In_{0.52}As). In this alloy, the aluminum content may be relatively high, with a concentration of 48%. Embodiments of the disclosure may provide for a new alloy with a lower aluminum content that may reduce oxidation of the electron and hole stopper material, and may be used in layer 202 or 312. In laser 300, the alloy may further allow for the removal of aluminum oxide prior to the regrowth of the current blocking material 302. In one embodiment, this material comprises an alloy of aluminum indium arsenide phosphide (Al_{0.3}In_{0.7}As_{0.5}P_{0.5}). By using this novel material, oxidation of the aluminum containing layers can be reduced allowing a buried ridge structure to be fabricated with high material quality at the newly formed interfaces with the current blocking material 302. As a result, the performance of laser 300 can exceed the performance of laser 100 when laser 100 uses Al_{0.48}In_{0.52}As. As will be discussed more fully with respect to FIG. 8, the novel material Al_{0.3}In_{0.7}As_{0.5}P_{0.5} has a lattice constant within 0.5% of the lattice constant of the substrate material InP.

Referring to FIG. 4, a cross-sectional view of a buried ridge type semiconductor laser 300 is shown. In FIG. 4, laser 300 is a semiconductor laser device that is adapted to produce a coherent laser beam of a specific optical frequency. Laser 300 contains p-type cladding 306 having ridge 304, active layer 308, and n-type cladding and substrate 310. Active layer 308 comprises electron stopper layer 312, Multi Quantum Well (MQW) active layer 314, and hole stopper layer 316. Further, laser 300 contains current blocking material 302. Electron stopper layer 312 may include an alloy of aluminum indium arsenide phosphide (e.g., Al_{0.3}In_{0.7}As_{0.5}P_{0.5}). Hole stopper layer 316 may similarly include an alloy of aluminum indium arsenide phosphide (e.g., Al_{0.3}In_{0.7}As_{0.5}P_{0.5}).

Referring to FIGS. 5A and 5B, an expanded view of the materials stack provided in laser 300 is shown. In FIGS. 5A and 5B, laser 300 contains p-type cladding 306, active layer 308, n-type cladding and substrate 310. Active layer 308 comprises electron stopper layer 312, MQW layer 314 and hole stopper layer 316. The MQW layer 314 may comprise any number of quantum well and barrier pairs.

As described above, active layer 308 is the region where electrons and holes recombine to generate laser light via stimulated emission of photons. Within active layer 308, a stack of quantum wells is provided in which laser light can be produced. A plurality of quantum wells is sandwiched between barrier materials to form the MQW structure seen in MQW layer 314. Although the quantum well and barrier layers can be made from any number of laser producing materials, these layers can be aluminum gallium indium arsenide. MQW layer 314 is sandwiched between electron stopper layer 312 and hole stopper layer 316 to complete the active region 308 of the laser 300. Typically, a separate confinement heterostructure, which simultaneously provides optical and some electronic confinement, is placed between the electron stopper layer 312 or hole stopper layer 316 and the MQW layer 314. Furthermore, one or more quantum wells of the MQW layer may be compressively or tensile strained relative to the substrate. One or more barrier layers may be compressively or tensile strained relative to the substrate. The one or more quantum wells and the one or more barrier layers may be of opposing strain such as to mitigate critical thickness issues. For example, one or more quantum wells of the MQW layer may be compressively strained relative to the substrate while one or more barrier layers is tensile strained relative to the substrate. Alternatively, for example, one or more quantum wells of the MQW layer may be tensile strained relative to the substrate while one or more barrier layers is compressively strained relative to the substrate. A lattice mismatch of a quantum well or a barrier may be ±2% relative to the substrate lattice constant.

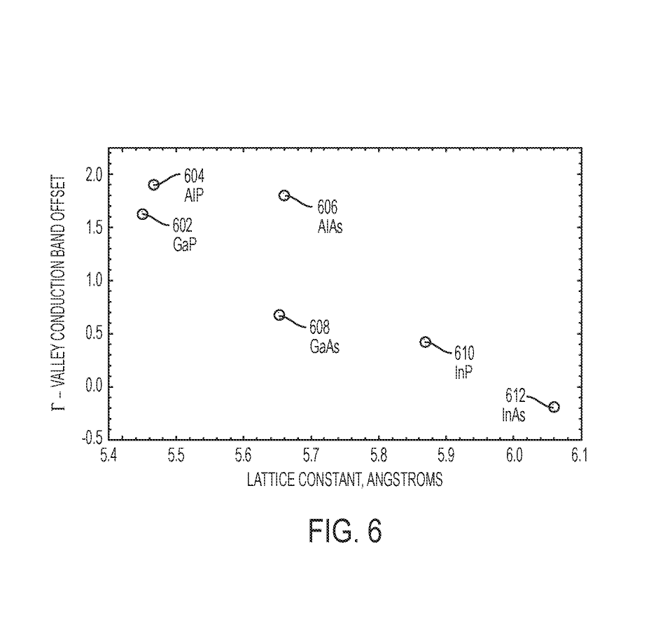

Referring to FIG. 6, a chart showing the lattice constants of selected materials used in semiconductor laser manufacturing is shown. The graph of FIG. 6 shows the lattice constants of six materials and the corresponding conduction band offsets, in electron Volts (eV), for those materials. Although it may usually be desirable to ensure all layers outside MQW layer 314 from FIG. 5 are lattice matched to reduce any undesirable material quality degradation mediated by strain mismatch, it is not uncommon to introduce a lattice mismatch within ±1% in a thin layer without compromising material quality. In semiconductor laser fabrication, materials may typically be formed from compounds of one group III element on the periodic table, in combination with one group V element. In the example of FIG. 6, six binary materials are shown as Gallium Phosphide (GaP) 602, Aluminum Phosphide (AlP) 604, Aluminum Arsenide (AlAs) 606, Gallium Arsenide (GaAs) 608, Indium Phosphide (InP) 610, and Indium Arsenide (InAs) 612. Each of these six materials has a particular lattice constant value, as well as a particular conduction band offset value. To function as an electron stopper, such as for electron stopper layer 312, it may be essential that the conduction band offset of the material used is larger than the conduction band offset of the layers surrounding it to prevent electron leakage from the MQW region to the p-InP.

Referring to FIG. 7, a chart showing the conduction band offset, in eV, against lattice constant for common substrate materials GaAs and InP. Conventional electron stopper materials lattice-matched to these substrates are shown. In the example of FIG. 7, an electron stopper made of material 702 comprising aluminum indium arsenide (Al_{0.48}In_{0.52}As) having a 48% aluminum composition is shown to have a lattice constant of 5.875 angstroms. The lattice constant of this material is the same as the lattice constant of a substrate made of material 704 comprising indium phosphide (InP). For this reason, as discussed above, these materials are typically used to form electron stopper layer 202 and substrate 112 in a typical ridge waveguide semiconductor laser 100. As can also be seen in FIG. 7, these materials are particularly well suited to be used as the substrate and electron stopper materials due to the high difference in conduction band offset values. For example, the conduction band offset of the electron stopper layer 702 is 0.7 eV, which is well above the conduction band offset of the substrate 704 at 0.4 eV. Higher differences in these values may be desired to create a sufficient barrier to electron leakage out of the MQW region and into the p-InP ridge. Also shown in FIG. 7 are two ternary electron stopper alloys lattice matched to GaAs with a lattice constant of 6.65 angstroms. These are aluminum indium phosphide (Al_{0.52}In_{0.48}P) and gallium indium phosphide (Ga_{0.5}In_{0.49}P).

As described above with reference to FIGS. 3 and 4, aluminum indium phosphide (Al_{0.48}In_{0.52}As) is an undesirable material to use in a buried ridge laser, such as laser 300, due to its relatively high (48%) aluminum content. For that reason, a new material comprising aluminum indium arsenide phosphide (Al_{0.3}In_{0.7}As_{0.5}P_{0.5}) with relatively lower (30%) aluminum content may be used as electron stopper layer 312 in laser 300.

Referring to FIG. 8, a chart showing the lattice constants of selected materials including the electron barrier material of FIGS. 3 and 4 is shown. The graph of FIG. 8 shows the lattice constants of the six materials in FIG. 7 and the corresponding conduction band offsets for those materials. In addition, the novel material aluminum indium arsenide phosphide (Al_{0.3}In_{0.7}As_{0.5}P_{0.5}) described in FIGS. 3 and 4 is shown. This alloy incorporates enough indium content to come within ±1% lattice mismatch to InP and retains a high conduction band offset.

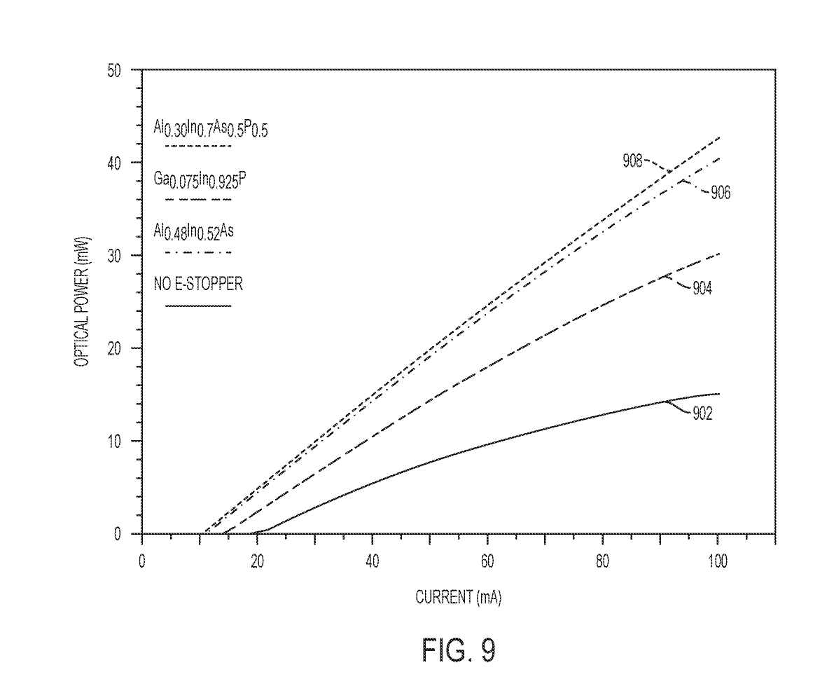

Referring to FIG. 9, a chart of the optical power output in milliwatts (mW) as a function of input current in milliamps (mA) for a variety of electron stopper materials in a ridge waveguide laser, such as laser 100, is shown. In particular, the graph of FIG. 9 shows the optical power output in milliwatts at various input currents for four different types of electron stoppers: no electron stopper 902, an electron stopper 904 comprised of Ga_{0.075}In_{0.925}P, an electron stopper 906 comprised of Al_{0.48}In_{0.52}As, and an electron stopper 908 comprised of Al_{0.3}In_{0.7}As_{0.5}P_{0.5}. As the chart shows, when no electron stopper 902 is used in the ridge waveguide laser, the optical power output approaches a maximum of less than 20 mW at 100 mA of current. By contrast, when an electron stopper 904 comprised of Ga_{0.075}In_{0.925}P is used, the output power approaches 30 mW at the same 100 mA of current supplied.

FIG. 9 further indicates the theoretical performance of an electron stopper 906 Al_{0.48}In_{0.52}As in a ridge waveguide laser. As the chart shows, this material would theoretically allow an output power of near 40 mW at 100 mA of current. However, as discussed above, the aluminum content of this material is too high to use in a laser with a buried ridge structure, because it will oxidize significantly during the fabrication process. While the chart in FIG. 9 shows the theoretical performance of this material in the absence of oxidation, (e.g., in a ridge waveguide structure), the actual performance of the material in a buried ridge laser would be significantly reduced, especially its long term reliability if the oxidation is present.

By contrast, FIG. 9 shows the improved performance of a ridge waveguide laser when an electron stopper 908 comprised of Al_{0.3}In_{0.7}As_{0.5}P_{0.5} is provided. As the chart shows, this material 908 is higher performing than all other materials in the chart at all current levels, with an output power of more than 40 mW at 100 mA of input current. In addition, unlike the material 906, material 908 has an aluminum content of 30%, which is suitable for use in a buried ridge laser (such as laser 300) and may reduce the undesirable oxidation described above and allow removal of any oxidation prior to regrowth. Thus, use of Al_{0.3}In_{0.7}As_{0.5}P_{0.5} as the electron stopper in either layer 202 of laser 100 or layer 312 of laser 300 provides substantial performance benefits over the use of previously known materials. Performance benefits are also shown when Al_{0.3}In_{0.7}As_{0.5}P_{0.5} is used in any high performance laser structure such as a buried ridge whose fabrication involves etching through and thus subjecting the aluminum containing layers to oxidation that is difficult to remove prior to regrowth. The computed theoretical performance when the aluminum content is reduced to 25% or 20%, giving an alloy of Al_{0.25}In_{0.75}As_{0.5}P_{0.5} and Al_{0.2}In_{0.8}As_{0.5}P_{0.5}, respectively, results in a laser threshold increase to 14.9 and 18.3 mA, respectively. The output power at 100 mA of input current reduces to 34.0 mW and 22.5 mW, respectively. In addition, increasing the aluminum content to 35% or 40%, giving an alloy of Al_{0.35}In_{0.65}As_{0.5}P_{0.5} and Al_{0.4}In_{0.6}As_{0.5}P_{0.5}, respectively, results in a negligible change in threshold current, in both cases, relative to Al_{0.3}In_{0.7}As_{0.5}P_{0.5}. The change in output power at 100 mA is also negligible for both cases relative to Al_{0.3}In_{0.7}As_{0.5}P_{0.5}. Thus, the preferred electron stopper 908 is Al_{0.3}In_{0.7}As_{0.5}P_{0.5}. However, variations in aluminum content of the aluminum indium arsenide phosphide alloy as described above can produce a similar laser threshold current and output power.

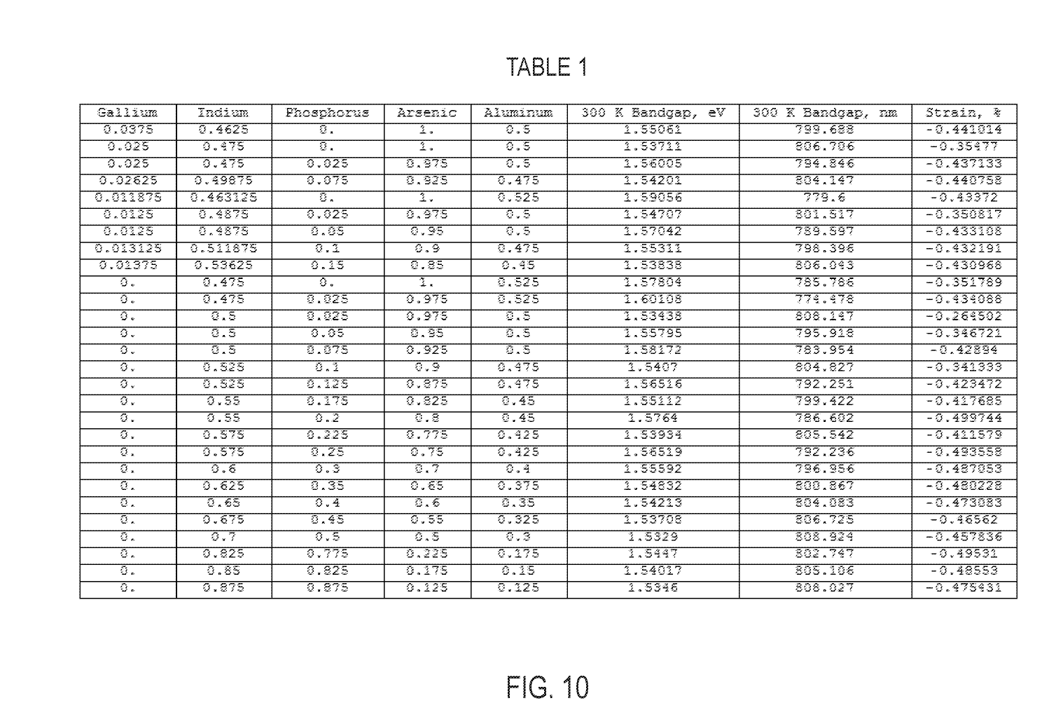

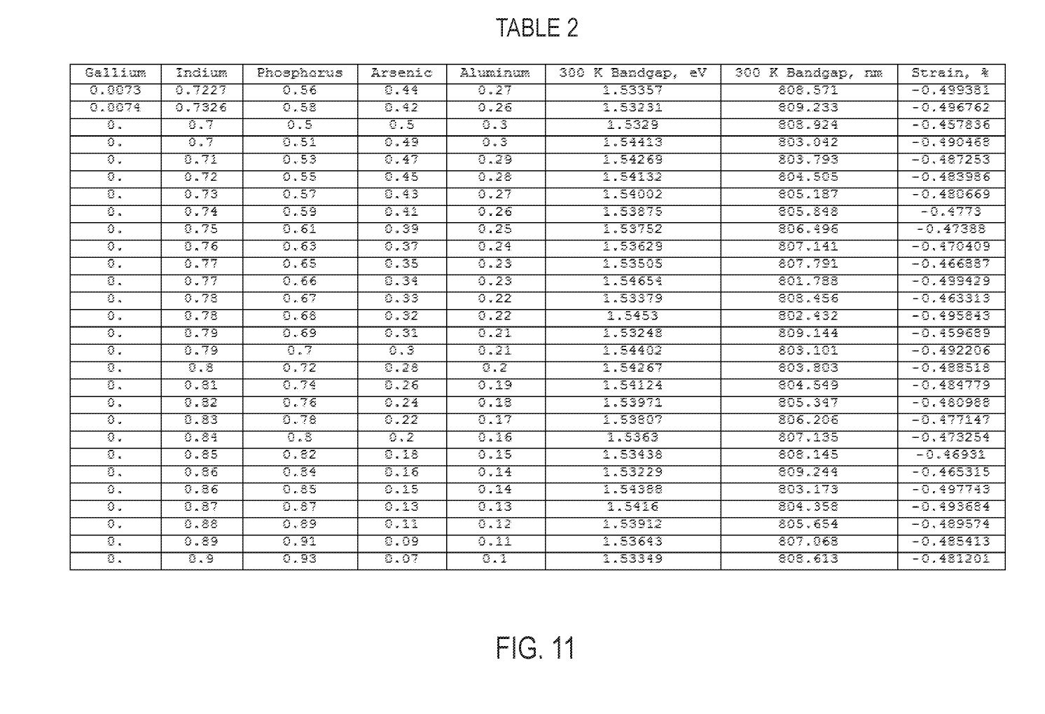

For example, an aluminum indium arsenide phosphide alloy may be represented by the following format: AlₓGa_{y}In_{(1-x-y)}As_{z}P_{(1-z)}, where the values x, y, 1, and z represent content amounts that reflect how much of each element is present in the alloy. There may exist a number of variations for the AlₓGa_{y}In_{(1-x-y)}As_{z}P_{(1-z)} alloy. FIG. 10 shows Table 1, which shows a list of AlₓGa_{y}In_{(1-x-y)}As_{z}P_{(1-z)} alloy content amounts based on two constraints. One constraint is that the bandgap be larger than 1.532 eV. A second constraint is that strain mismatch relative to an InP substrate be no more than ±0.5%. FIG. 11 shows Table 2, which shows another list of AlₓGa_{y}In_{(1-x-y)}As_{z}P_{(1-z)} alloy content amounts where a further constraint is imposed, namely, that the aluminum content be no greater than 30%. Both tables are provided for illustrative purposes and are not an exhaustive list of possible alloy combinations.

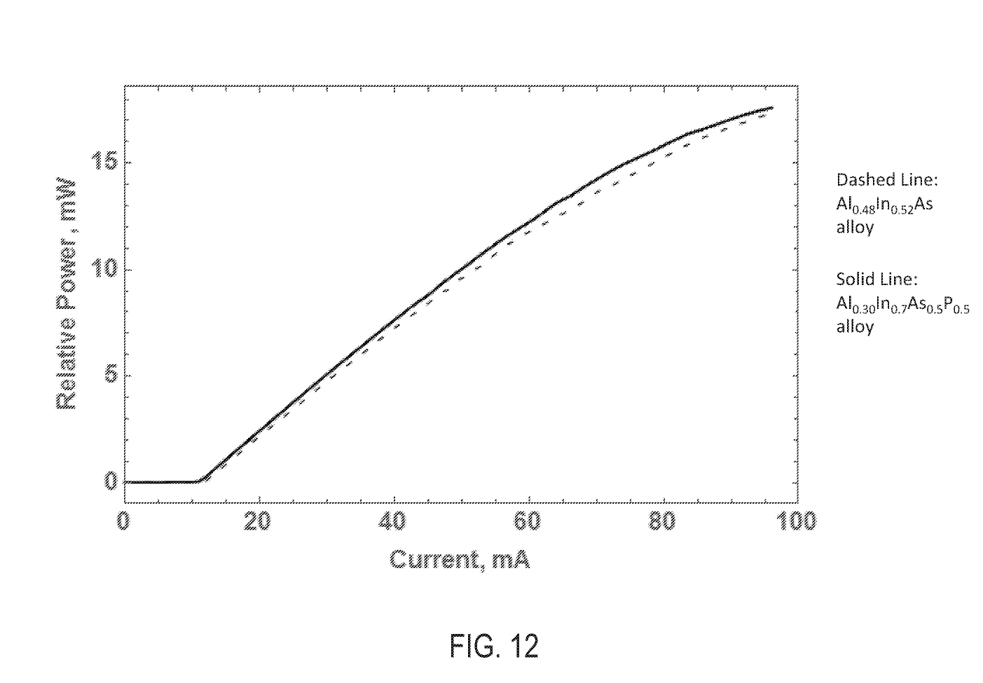

FIG. 12 shows a chart of experimental results of optical power output for electron stopper materials in semiconductor lasers in accordance with an embodiment of the present disclosure. Otherwise identical laser stacks were grown with different electron stopper layers. One laser stack included an electron stopper layer made of an Al_{0.48}In_{0.52}As alloy. The other laser stack included an electron stopper layer made of an Al_{0.3}In_{0.7}As_{0.5}P_{0.5} alloy. Laser structures from each laser stack were fabricated and tested. In testing, input current was increased for each laser and relative power (e.g., optical power) was measured. The results are plotted in the chart of FIG. 10. The dashed line in the chart shows the experimental results for a laser that has an Al_{0.48}In_{0.52}As alloy electron stopper layer. The solid line in the chart shows the experimental results for a laser that has an Al_{0.3}In_{0.7}As_{0.5}P_{0.5} alloy electron stopper layer.

As shown by FIG. 12, the Al_{0.3}In_{0.7}As_{0.5}P_{0.5} alloy laser performs at least as well as the Al_{0.48}In_{0.52}As alloy laser with the added benefit that the aluminum content has been reduced from 48 to 30% making it suitable for laser structures such as buried heterostructure lasers. In addition, accelerated aging tests have shown that there is negligible variation from the results shown in FIG. 10 after the Al_{0.3}In_{0.7}As_{0.5}P_{0.5} alloy laser has been running for 2000 hours.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of at least one particular implementation in at least one particular environment for at least one particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A semiconductor laser comprising:
a substrate;
an active region; and
an electron stopper layer including an aluminum gallium indium arsenide phosphide alloy having an AlₓGa_{y}In_{(1-x-y)}As_{z}P_{(1-z)} composition.

2. The semiconductor laser of claim 1, wherein the content amount x of the AlₓGa_{y}In_{(1-x-y)}As_{z}P_{(1-z)} composition ranges from 0.20 to 0.55.

3. The semiconductor laser of claim 1, wherein the content amount y of the AlₓGa_{y}In_{(1-x-y)}As_{z}P_{(1-z)} composition is 0, and the AlₓGa_{y}In_{(1-x-y)}As_{z}P_{(1-z)} composition has an Al_{0.3}In_{0.7}As_{0.5}P_{0.5} composition.

4. The semiconductor laser of claim 1, wherein the content amount y of the AlₓGa_{y}In_{(1-x-y)}As_{z}P_{(1-z)} composition is 0, and the AlₓGa_{y}In_{(1-x-y)}As_{z}P_{(1-z)} composition has an Al_{0.35}In_{0.65}As_{0.5}P_{0.5} composition.

5. The semiconductor laser of claims 1, wherein the content amount y of the AlₓGa_{y}In_{(1-x-y)}As_{z}P_{(1-z)} composition is 0, and the AlₓGa_{y}In_{(1-x-y)}As_{z}P_{(1-z)} composition has an Al_{0.4}In_{0.6}As_{0.5}P_{0.5} composition.

6. The semiconductor laser of claims 1, wherein a lattice constant of the electron stopper layer is matched to a lattice constant of the substrate.

7. The semiconductor laser of claims 1, wherein a lattice constant of the electron stopper layer has a lattice mismatch relative to a lattice constant of the substrate.

8. The semiconductor laser of claim 7, wherein the lattice constant of the electron stopper layer has a lattice mismatch within ±1% relative to the lattice constant of the substrate.

9. The semiconductor laser of claim 1, wherein the substrate comprises indium phosphide (InP).

10. The semiconductor laser of claim 1, wherein the content amount y of the AlₓGa_{y}In_{(1-x-y)}As_{z}P_{(1-z)} composition is 0, and the AlₓGa_{y}In_{(1-x-y)}As_{z}P_{(1-z)} composition is an AlₓIn₍₁₋ₓ₎As_{z}P_{(1-z)} composition.

11. The semiconductor laser of claim 1, further comprising an n-type cladding layer, a multi quantum well (MQW) active layer arranged adjacent to the n-type cladding layer, and a p-type cladding layer arranged adjacent to the electron stopper layer, wherein the electron stopper layer is arranged between the MQW active layer and the p-type cladding layer, and the p-type cladding layer includes a ridge waveguide structure.

12. The semiconductor laser of claim 11, further comprising a hole stopper layer arranged adjacent to the n-type cladding layer, wherein the hole stopper layer includes an aluminum gallium indium arsenide phosphide alloy having an AlₓGa_{y}In_{(1-x-y)}As_{z}P_{(1-z)} composition, where the content amount x ranges from 0.20 to 0.55.

13. The semiconductor laser of claim 12, wherein the content amount y of the AlₓGa_{y}In_{(1-x-y)}As_{z}P_{(1-z)} composition is 0, and the AlₓGa_{y}In_{(1-x-y)}As_{z}P_{(1-z)} composition is an AlₓIn₍₁₋ₓ₎As_{z}P_{(1-z)} composition.

14. The semiconductor laser of claim 11, wherein a quantum well of the MQW active layer is compressively strained and a barrier of the MQW active layer is tensile strained, a lattice mismatch of the quantum well relative to a lattice constant of the substrate is within 2%, and a lattice mismatch of the barrier relative to the lattice constant of the substrate is within 2%.

15. The semiconductor laser of claim 11, wherein a quantum well of the MQW active layer is tensile strained and a barrier of the MQW active layer is compressively strained, a lattice mismatch of the quantum well relative to a lattice constant of the substrate is within 2%, and a lattice mismatch of the barrier relative to the lattice constant of the substrate is within 2%.

16. A semiconductor laser comprising:
a substrate;
an active region;
a lateral current blocking material; and
an electron stopper layer configured to reduce oxidation and form an interface with the current blocking material, wherein the electron stopper layer includes an aluminum gallium indium arsenide phosphide alloy having an AlₓGa_{y}In_{(1-x-y)}As_{z}P_{(1-z)} composition.

17. The semiconductor laser of claim 16, wherein the content amount x of the AlₓGa_{y}In_{(1-x-y)}As_{z}P_{(1-z)} composition ranges from 0.20 to 0.55.

18. The semiconductor laser of claim 16, wherein the content amount y of the AlₓGa_{y}In_{(1-x-y)}As_{z}P_{(1-z)} composition is 0, and the AlₓGa_{y}In_{(1-x-y)}As_{z}P_{(1-z)} composition has an Al_{0.3}In_{0.7}As_{0.5}P_{0.5} composition.

19. The semiconductor laser of claim 16, wherein the content amount y of the AlₓGa_{y}In_{(1-x-y)}As_{z}P_{(1-z)} composition is 0, and the AlₓGa_{y}In_{(1-x-y)}As_{z}P_{(1-z)} composition has an Al_{0.35}In_{0.65}As_{0.5}P_{0.5} composition.

20. The semiconductor laser of claims 16, wherein the content amount y of the AlₓGa_{y}In_{(1-x-y)}As_{z}P_{(1-z)} composition is 0, and the AlₓGa_{y}In_{(1-x-y)}As_{z}P_{(1-z)} composition has an Al_{0.4}In_{0.6}As_{0.5}P_{0.5} composition.

21. The semiconductor laser of claim 16, wherein a quantum well of an MQW active layer is compressively strained and a barrier of the MQW active layer is tensile strained, a lattice mismatch of the quantum well relative to a lattice constant of the substrate is within 2%, and a lattice mismatch of the barrier relative to the lattice constant of the substrate is within 2%.

22. The semiconductor laser of claim 16, wherein a quantum well of an MQW active layer is tensile strained and a barrier of the MQW active layer is compressively strained, a lattice mismatch of the quantum well relative to a lattice constant of the substrate is within 2%, and a lattice mismatch of the barrier relative to the lattice constant of the substrate is within 2%.

23. A method of fabricating a semiconductor laser comprising:
arranging an n-type cladding layer on a substrate;
arranging a hole stopper layer on the n-type cladding layer;
arranging a multi quantum well (MQW) active layer on the hole stopper layer;
arranging an electron stopper layer on a multi quantum well (MQW) active layer; and
arranging a current blocking material adjacent to the n-type cladding layer, hole stopper layer, MQW active layer, and electron stopper layer,
wherein the electron stopper layer is configured to reduce oxidation and form an interface with the current blocking material, and includes an aluminum gallium indium arsenide phosphide alloy having an AlₓGa_{y}In_{(1-x-y)}As_{z}P_{(1-z)} composition.

24. The method of claim 23, wherein the content amount x of the AlₓGa_{y}In_{(1-x-y)}As_{z}P_{(1-z)} composition ranges from 0.20 to 0.55.

25. The method of claim 23, wherein a quantum well of the MQW active layer is compressively strained and a barrier of the MQW active layer is tensile strained, a lattice mismatch of the quantum well relative to a lattice constant of a substrate is within 2%, and a lattice mismatch of the barrier relative to the lattice constant of the substrate is within 2%.

26. The method of claim 23, wherein a quantum well of the MQW active layer is tensile strained and a barrier of the MQW active layer is compressively strained, a lattice mismatch of the quantum well relative to a lattice constant of a substrate is within 2%, and a lattice mismatch of the barrier relative to the lattice constant of the substrate is within 2%.
